(19) United States
(12) Patent Application Publication
(10) Pub. No.: US 2013/0048349 A1
(43) Pub. Date: Feb. 28, 2013

(54) TRANSPARENT CONDUCTIVE FILM AND TOUCH PANEL USING THE SAME

(71) Applicants: MING-TIEN LIN, Tu-Cheng (TW); PO-SHENG SHIH, Tu-Cheng (TW)

(72) Inventors: MING-TIEN LIN, Tu-Cheng (TW); PO-SHENG SHIH, Tu-Cheng (TW)

(73) Assignee: SHIH HUA TECHNOLOGY LTD., Miaoli (TW)

(21) Appl. No.: 13/340,134

(22) Filed: Dec. 29, 2011

(30) Foreign Application Priority Data
Aug. 31, 2011 (TW) 100131260

(51) Int. Cl. H05K 1/03; H05K 1/02

(52) U.S. Cl. 174/255; 174/250; 977/742; 977/952

(57) ABSTRACT

A transparent conductive film includes at least one continuous transparent conductive layer and a number of transparent conductive stripes spaced from each other and extending substantially along a low impedance direction. The transparent conductive stripes are disposed on and electrically contact a surface of the at least one transparent conductive layer. A resistivity of the transparent conductive film in the low impedance direction is less than the resistivity in any other direction. A touch panel includes the transparent conductive film.

This application claims all benefits accruing under 35 U.S.C. §119 from Taiwan Patent Application No. 100131260, filed on Aug. 31, 2011, in the Taiwan Intellectual Property Office, the contents of which are hereby incorporated by reference. This application is related to commonly-assigned applications entitled, “TRANSPARENT CONDUCTIVE FILM AND TOUCH PANEL USING THE SAME,” filed **** (Atty. Docket No. US39774); and “TRANSPARENT CONDUCTIVE FILM AND TOUCH PANEL USING THE SAME,” filed **** (Atty. Docket No. US41147).

### BACKGROUND

1. Technical Field

The present disclosure relates to a transparent conductive film and a touch panel using the same.

2. Description of Related Art

The main component of touch panels are transparent conductive films as touch sensing mediums. Materials such as indium tin oxide (ITO), stannic oxide (SnO₂), and zinc oxide (ZnO) are commonly used transparent conductive film materials. ITO has been widely used in the touch panels because it has a high light transmittance, good conductivity, and easily etched.

However, the touch panels can only detect a single touch at one time, and a detecting precision is relatively low.

What is needed, therefore, is to provide a transparent conductive film and a touch panel using the transparent conductive film which can realize multi-touch detecting and can improve the detecting precision of touch points operated thereon.

### BRIEF DESCRIPTION OF THE DRAWING

Many aspects of the present disclosure can be better understood with reference to the following drawings. The components in the drawings are not necessarily to scale, the emphasis instead being placed upon clearly illustrating the principles of the present embodiments.

FIG. 1 is a top view of an embodiment of a transparent conductive film.

FIG. 2 is a top view of an embodiment of the transparent conductive film including a plurality of discontinuous transparent conductive stripes.

FIG. 3 is a top view of an embodiment of the transparent conductive film including a plurality of waved stripes.

FIG. 4 is a top view of an embodiment of the transparent conductive film including a plurality of transparent conductive stripes with varied widths.

FIG. 5 is a top view of the transparent conductive film of Example 1.

FIG. 6 is a top view of the transparent conductive film of Example 2.

FIG. 7 is a top view of an embodiment of a touch panel.

FIG. 8 is a side view of the touch panel.

FIG. 9 is a chart showing variation value curves of voltage of touch points acted on the touch panel.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean at least one.

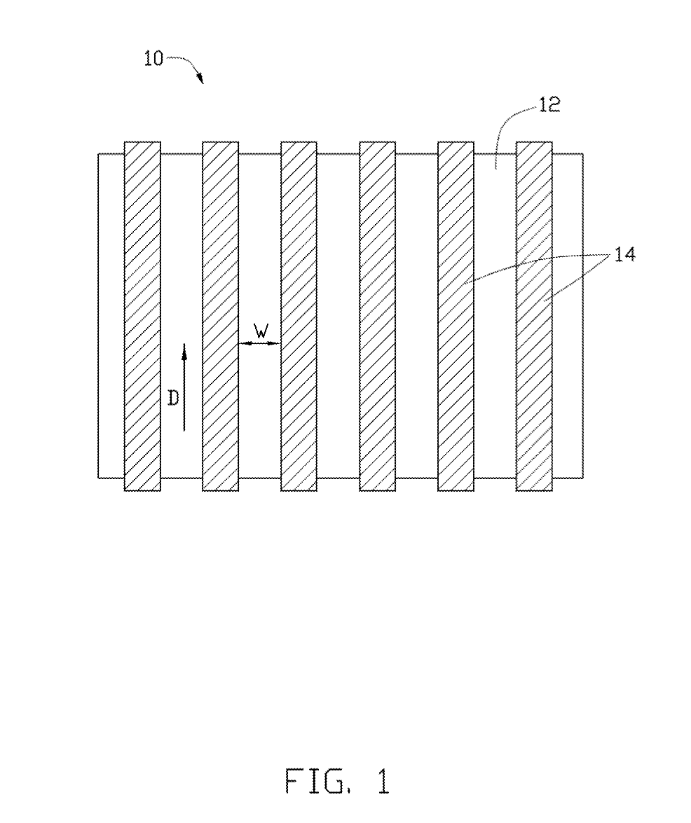

Referring to FIG. 1, one embodiment of a transparent conductive film 10 includes at least one continuous transparent conductive layer 12 and a plurality of transparent conductive stripes 14 spaced from each other and extending substantially along a first direction. The plurality of transparent conductive stripes 14 are disposed on and electrically contact a surface of the transparent conductive layer 12. The first direction can be a low impedance direction D of the transparent conductive film 10. A resistivity of the transparent conductive film 10 in the low impedance direction D is less than the resistivity in any other direction.

The transparent conductive film 10 can electrically conduct in any direction, and the resistivity is the smallest in one direction thereof. The one direction is defined as the low impedance direction D. The low impedance direction D is substantially parallel with a surface of the transparent conductive film 10. The resistivity of the transparent conductive film 10 in the low impedance direction D is less than the resistivity in any other direction substantially parallel with the surface of the transparent conductive film 10. The plurality of transparent conductive stripes 14 are electrically connected with other via the transparent conductive layer 12.

The transparent conductive layer 12 can have substantially the same resistivity in any direction parallel with the surface thereof. In one embodiment, the transparent conductive layer 12 is a uniform and continuous layered structure. The resistivity of the transparent conductive layer 12 is greater than the resistivity of the plurality of transparent conductive stripes 14 along the extending direction. A resistivity ratio of the transparent conductive layer 12 and the plurality of transparent conductive stripes 14 along the extending direction can be in a range from about 1:100 to about 1:1000. In one embodiment, the resistivity is in a range from about 1:100 to about 1:400.

The transparent conductive layer 12 can have different resistivities in different directions substantially parallel with the surface thereof, thus having an anisotropy impedance. Anisotropic impedance means that the transparent conductive film 10 has different impedances along different directions substantially parallel with a surface of the transparent conductive film 10. In one embodiment, the transparent conductive layer 12 can be a carbon nanotube drawn film drawn from a carbon nanotube array. A majority of carbon nanotubes in the carbon nanotube drawn film are joined end to end and extend substantially along a same direction. The carbon nanotube drawn film is capable of forming a free-standing structure. The term “free-standing structure” can be defined as a structure that does not need to be supported by a substrate. For example, a free standing structure can sustain the weight of itself when it is hoisted by a portion thereof without any significant damage to its structural integrity. So, if the carbon nanotube drawn film is placed between two separate supporters, a portion of the carbon nanotube drawn film, not in contact with the two supporters, would be suspended between the two supporters and yet maintain film structural integrity. The free-standing structure of the carbon nanotube drawn film is realized by the successive carbon nanotubes joined end to end by van der Waals attractive forces. The carbon nanotube drawn film has a smallest resistivity in one direction substantially parallel with the surface thereof, and the smallest resistivity is greater than the resistivity of the plurality of transparent conductive stripes 14 along the extending direction. The transparent conductive layer 12 can be one or a plurality of the carbon nanotube drawn films stacked with each other. A number of the carbon nanotube drawn films can be adjusted according to a light transmittance of the transparent conductive film 10.

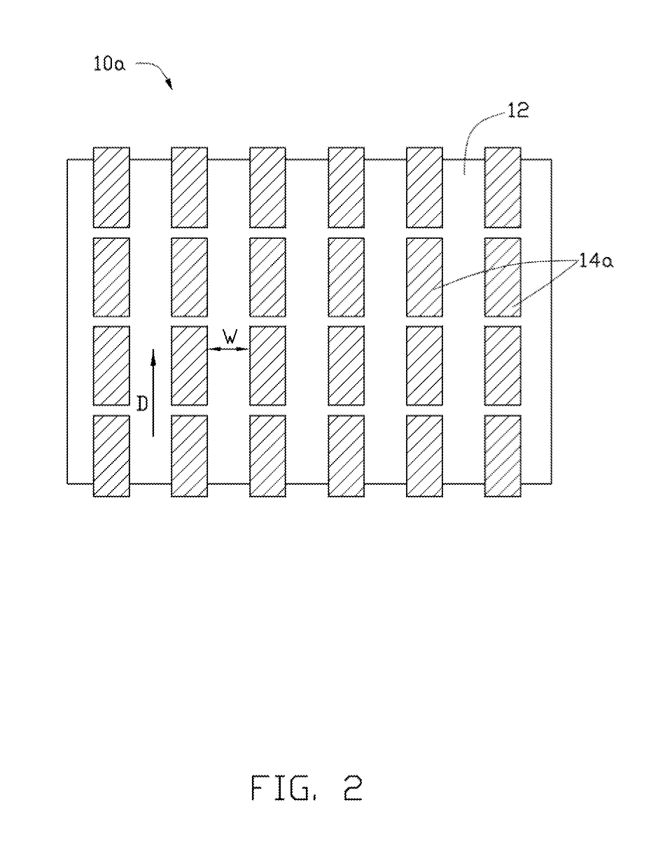

The plurality of transparent conductive stripes 14 can have a uniform resistivity or non-uniform resistivity. One of the plurality of transparent conductive stripes 14 can be continuous or discontinuous. The transparent conductive layer 12 has two opposite sides along the low impedance direction D. Referring to FIG. 1, the term “continuous” means that one transparent conductive stripe 14 extends from one of the two opposite sides of the transparent conductive layer 12 to the other one of the two opposite sides along the low impedance direction D. The continuous transparent conductive stripe 14 along the extending direction can be longer than or as long as the transparent conductive layer 12 along the low impedance direction D. Referring to FIG. 2 of a transparent conductive film 10a, the term “discontinuous” means that one of the plurality of transparent conductive stripes 14a includes a plurality of sub-conductive stripes spaced with each other and arranged in a line substantially along the extending direction. The transparent conductive stripe 14a formed by the plurality of sub-conductive stripes can increase the light transmittance of the transparent conductive film 10a.

Both the transparent conductive layer 12 and the plurality of transparent conductive stripes 14 can be formed by using a transparent conductive material. The material of the transparent conductive layer 12 and the plurality of transparent conductive stripes 14 can be the same or different as long as the resistivity of the transparent conductive film 10 substantially along the low impedance direction D is less than the resistivity along any other direction. In one embodiment, the material of the transparent conductive layer 12 is different from the material of the plurality of transparent conductive stripes 14. The material with a high resistivity is selected to form the transparent conductive layer 12. The material with a low resistivity, compared with the transparent conductive layer 12, is selected to form the plurality of transparent conductive stripes 14.

The transparent conductive material can be a metal oxide, a metal nitride, a metal fluoride, a conductive polymer, a carbon containing material, or combinations thereof. The metal oxide can include a single metal element such as stannic oxide (SnO₂), zinc oxide, cadmium oxide (CdO), or indium oxide (In₂O₃). The metal oxide can also include two or more metal elements such as indium tin oxide (ITO), indium zinc oxide (IZO), gallium zinc oxide (GZO), aluminum zinc oxide (AZO). The metal oxide can be a mixture of at least two metal oxides such as In₂O₃—ZnO, CdIn₂O₄, Zn₂SnO₄, or combinations thereof. The metal nitride can be titanium nitride (TiN). The metal fluoride can be fluoride mixed stannic oxide. The conductive polymer can be poly(3,4-ethylenedioxythiophen) (PEDOT) or a composition of PEDOT and polystyrene sulfonate (PEDOT-PSS). The carbon containing material can be graphene or carbon nanotubes. The transparent conductive layer 12 and the plurality of transparent conductive stripes 14 can be a transparent graphene sheet or a carbon nanotube transparent conductive film. The carbon nanotube transparent conductive film can be a transparent conductive film consisting of carbon nanotubes or a composite film including the carbon nanotubes and other transparent conductive materials.

The transparent conductive film 10 can be made by various methods as long as the plurality of transparent conductive stripes 14 on a surface of the transparent conductive layer 12 have a resistivity vary with the direction. The transparent conductive film 10 has the lowest impedance direction. The plurality of transparent conductive stripes 14 can have a low resistivity and extend along a same direction (e.g., the lowest impedance direction of the transparent conductive film 10), and the transparent conductive layer 12 can have a uniform and high resistivity.

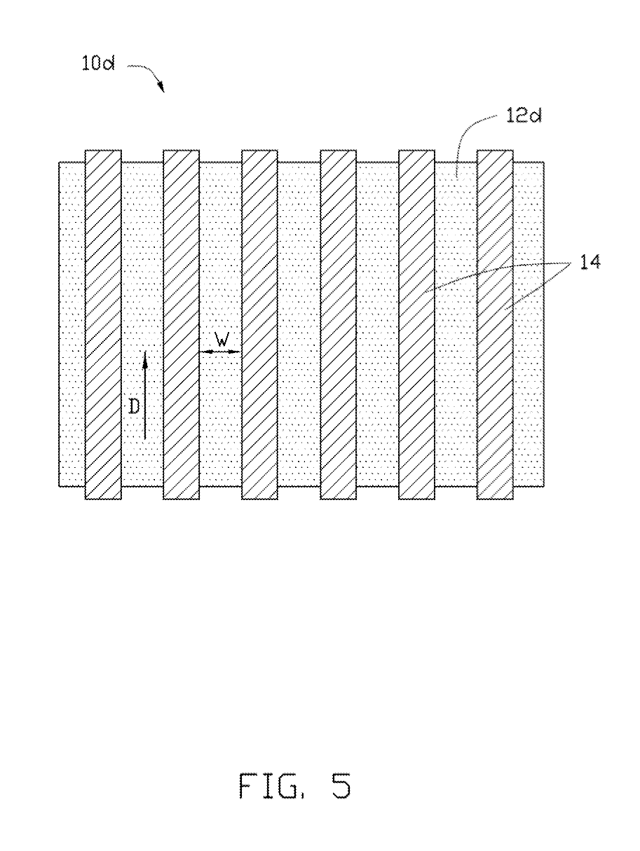

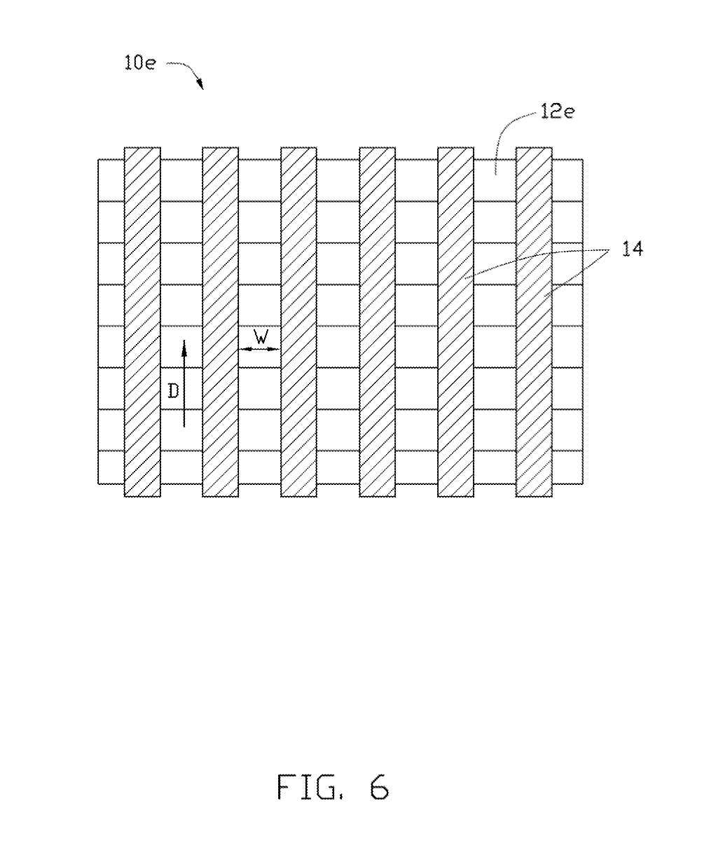

Referring to FIG. 5, in one embodiment of the transparent conductive film 10d, the material of the transparent conductive layer 12d is a composite of carbon nanotubes and a transparent conductive polymer, such as the composite of the carbon nanotubes and PEDOT-PSS, and the material of the plurality of transparent conductive stripes 14 is ITO. The carbon nanotubes are disorderly distributed in the transparent conductive layer 12. Referring to FIG. 6, in one embodiment of a transparent conductive film 10e, the transparent conductive layer 12e is the carbon nanotube drawn film. The material of the plurality of transparent conductive stripes 14 is ITO. The carbon nanotube drawn film can be directly laid on a surface of the plurality of spaced ITO transparent conductive stripes 14 to form the transparent conductive film 10e.

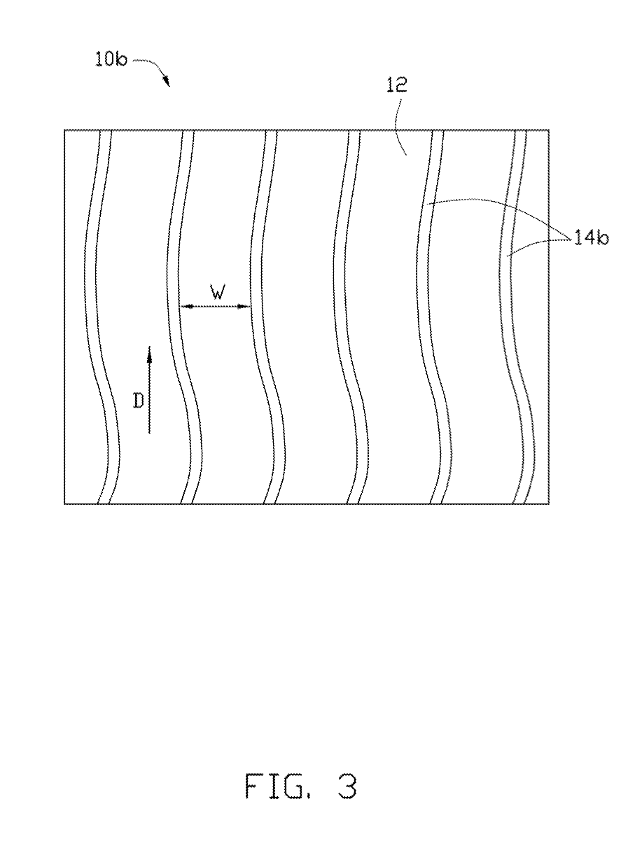

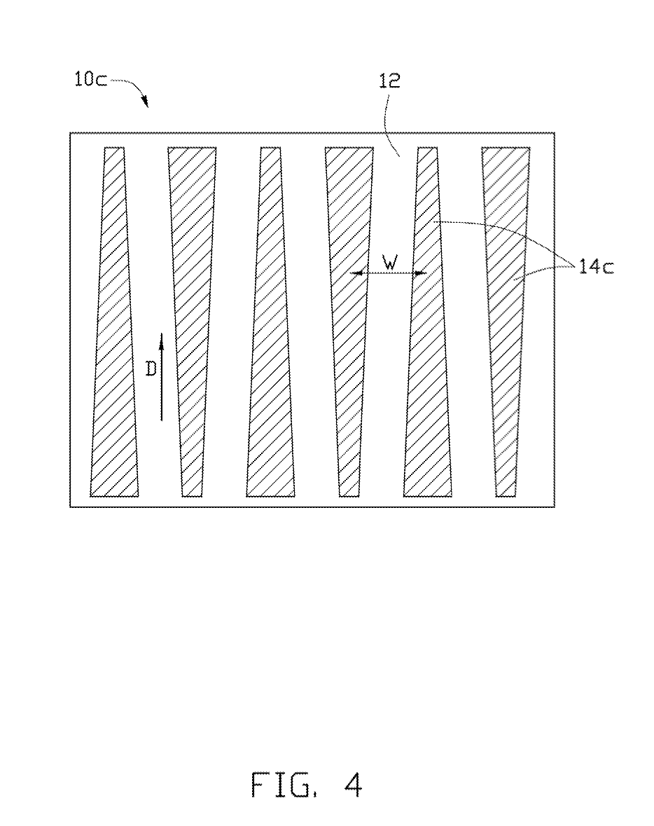

The plurality of transparent conductive stripes 14 can have various shapes as long as the resistivity of the transparent conductive film 10 along the low impedance direction D is much less than the resistivity in any other direction. At least one of the plurality of transparent conductive stripes 14 can be a straight stripe, a square wave stripe, a waved stripe, a zigzag stripe, a stepped shaped stripe, or a cambered stripe. Referring to FIG. 1, in one embodiment, each of the plurality of transparent conductive stripes 14 is the straight stripe. Referring to FIG. 3, in one embodiment of a transparent conductive film 10b, each of the plurality of transparent conductive stripes 14b is the waved stripe and extends substantially along the low impedance direction D from one side of the transparent conductive film to an opposite side. Each of the plurality of transparent conductive stripes 14 can have an equal width or a varied width. Referring to FIG. 4, in one embodiment of a transparent conductive film 10c, each of the plurality of transparent conductive stripes 14c has the varied width. A conductive diversity of the transparent conductive film 10 in the different directions can be increased by varying the shapes of the transparent conductive stripes 14.

A distance between adjacent transparent conductive stripes 14 can be substantially the same or varied. The distance between adjacent transparent conductive stripes 14 may be set so as not to be visually sensed. The distance between two adjacent transparent conductive stripes 14 is labeled with W. In one embodiment, the plurality of transparent conductive stripes 14 is disposed at a substantially same distance. The distance W can be less than or equal to about 50 micrometers. In one embodiment, W is about 30 micrometers.

The transparent conductive film 10 can be formed by following steps:

S1, forming the plurality of transparent conductive stripes 14 spaced with each other and extending substantially along the same direction; and

S2, disposing the transparent conductive layer 12 on a surface of the spaced plurality of transparent conductive stripes 14 to form the transparent conductive film 10.

In step S1, the plurality of transparent conductive stripes 14 can be formed first, and then laid on a substrate and spaced from each other. In addition, the substrate can be provided first, the plurality of transparent conductive stripes 14 are directly formed on the surface of the substrate. In one embodiment, the step S1 includes the following sub-steps:

S11, disposing the transparent conductive material with a low resistivity on a surface of the substrate to form a continuous film; and

S12, patterning the continuous film to form the plurality of transparent conductive stripes 14 spaced from each other and extending substantially along a same direction.

In step S11, the substrate is a supporting component, and can be a transparent substrate. A material of the transparent substrate can be a glass or transparent polymer. The transparent polymer can be polymethylmethacrylate (PMMA), polyethylene terephthalate (PET), polycarbonate (PC), or combinations thereof. The continuous film can be formed by a method selected from the group consisting of vacuum evaporation, sputtering, ion plating, vacuum plasma CVD, spray pyrolysis, thermal CVD, and sol-gel. In one embodiment, ITO is sputtered on the surface of the substrate to form the continuous film.

In step S12, the patterning process is conducted based on a desired structure of the transparent conductive film 10 and the confirmation of the low impedance direction D. The patterning method can be bump transfer printing, wet etching, dry etching, laser etching, shave removing, or tape peeling. In one embodiment, the plurality of transparent conductive stripes 14 are patterned by laser etching the continuous film of ITO.

In step S2, the transparent conductive layer 12 can be formed first, and then covered on a surface of the plurality of spaced transparent conductive stripes 14. The transparent conductive layer 12 can also be directly formed on the surface of the plurality of spaced transparent conductive stripes 14. In one embodiment, the transparent conductive layer 12 is formed by mixing the carbon nanotubes and a PEDOT-PSS solution to form a coating solution, and coating the coating solution on the surface of the substrate having the plurality of transparent conductive stripes 14 disposed thereon to cover the plurality of transparent conductive stripes 14. In one embodiment, the transparent conductive layer 12 is the carbon nanotube drawn film 10. The steps S1 and S2 can be exchanged in the above method.

The following examples further illustrate transparent conductive film 10 and the method for making thereof.

### EXAMPLE 1

Referring to FIG. 5, the transparent conductive materials of ITO are sputtered on the surface of the substrate of PET to form the continuous film. The continuous film is laser etched to form the plurality of transparent conductive stripes 14 along the low impedance direction. Each of the plurality of transparent conductive stripes 14 is the straight stripe and has a substantially same width. Carbon nanotube powders and a transparent conductive polymer solution of PEDOT-PSS are mixed to form the coating solution. The coating solution is uniformly coated on the surface of the PET having the plurality of transparent conductive stripes 14 disposed thereon. The coated PET is dried to form the transparent conductive layer 12d.

### EXAMPLE 2

Referring to FIG. 6, the plurality of transparent conductive stripes 14 is fabricated by the same process as in Example 1, except that the transparent conductive layer 12e is a carbon nanotube drawn film drawn from the carbon nanotube array. The carbon nanotube drawn film has viscosity itself. Therefore, the carbon nanotube drawn film is directly adhered on the surface of the plurality of spaced transparent conductive stripes 14 to form the transparent conductive film 10e. The extending direction of the majority of carbon nanotubes is substantially perpendicular to the extending direction of the plurality of ITO transparent conductive stripes 14 in the transparent conductive film 10e.

One embodiment of a touch panel includes at least one transparent conductive film 10, a substrate, and a plurality of electrodes. The at least one transparent conductive film 10 is disposed on a surface of the substrate and capable of sensing the touch points on the touch panel. The plurality of electrodes are spaced from each other and electrically connected with the at least one transparent conductive film 10. In one embodiment, the plurality of electrodes is disposed on one side or two opposite sides of the touch panel. The one or two opposite sides are substantially perpendicular to the low impedance direction D.

The touch panel can be a resistive touch panel or a capacitive touch panel. The touch panel can realize a multi-touch detecting by using the transparent conductive film 10. In addition, signals detected from the plurality of electrodes before and after touching on the touch panel vary because of the anisotropic impedance of the transparent conductive film 10. Therefore, position coordinates of the touch points can be easily detected, and a precision of the detection is improved.

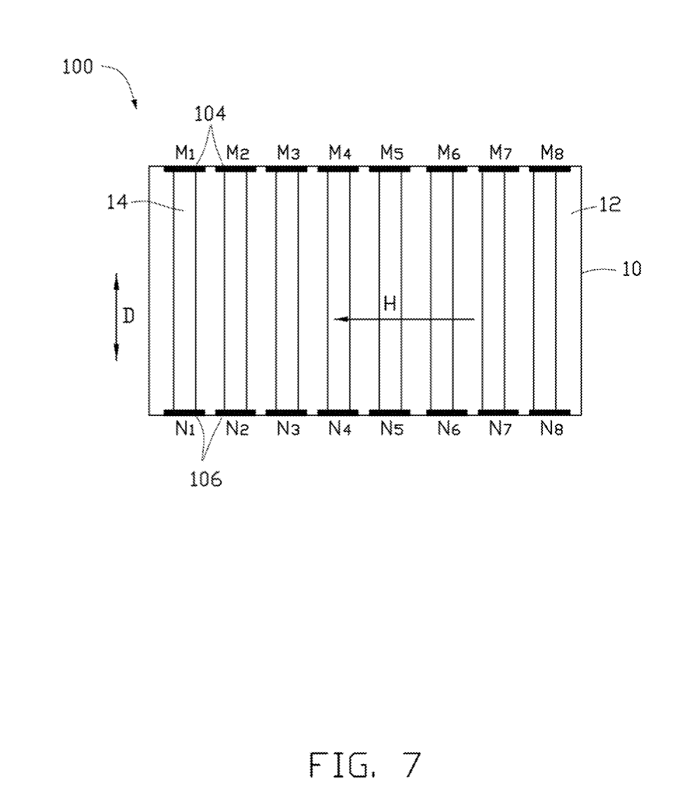

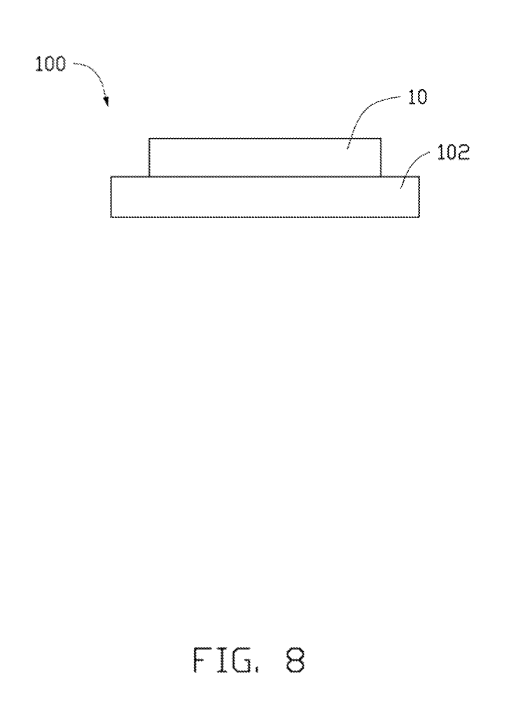

Referring to FIG. 7 and FIG. 8, one embodiment of a surface capacitive touch panel 100 using a single transparent conductive film 10 is provided. The touch panel 100 includes a substrate 102, the single transparent conductive film 10, and a plurality of first electrodes 104 and a plurality of second electrodes 106. The transparent conductive film 10 is disposed on a surface of the substrate 102. The plurality of first electrodes 104 and the plurality of second electrodes 106 are disposed on two opposite sides of the transparent conductive film 10. Both of the two opposite sides are substantially perpendicular to the low impedance direction D of the transparent conductive film 10. The side of the transparent conductive film 10 with the plurality of first electrodes disposed thereon is defined as a first side 112, and the side of the transparent conductive film 10 with the plurality of second electrodes disposed thereon is defined as a second side 114. Each of the plurality of first electrodes 102 corresponds to each of the plurality of second electrodes 104 along the low impedance direction D.

In one embodiment, the transparent conductive film 10 of FIG. 1 is used in the touch panel 100. The number of the plurality of first transparent conductive stripes 12 can be greater than or equal to the number of the plurality of first electrodes 104 or the plurality of second electrodes 106. In one embodiment, the number of the plurality of first transparent conductive stripes 12 is equal to the number of the plurality of first electrodes 104 and the number of the plurality of second electrodes 106. One end of the first transparent conductive stripe 12 along the extending direction is electrically connected with one first electrode 104, and the other end along the extending direction is electrically connected with one second electrode 106. The plurality of first electrodes 104 and second electrodes 106 can be driving electrodes used for inputting driving signals to drive the touch panel 100 and can be sensing electrodes used for detecting sensed signals. A driving and sensing process can be realized by a control circuit in the touch panel 100.

When a conductor, such as fingers or other conductors, touches the touch panel 100, a coupling capacitance can be generated between the conductor and the transparent conductive film 10. The coupling capacitance will cause a signal variation detected from the first electrodes 104 and second electrodes 106 before and after touching. The touch points can be detected according to the signal variation. The touch points can be detected according to the following steps:

B1, providing a driving signal to each of the plurality of first electrodes 104 and each of the plurality of second electrodes 106;

B2, touching the touch panel 100 by using the conductor to generate the coupling capacitance;

B3, detecting sensed signals from the plurality of first electrodes 104 and the plurality of second electrodes 106; and

B4, calculating position coordinates of the touch points by analyzing the sensed signals.

In step B1, the driving signal can be voltage or current. In one embodiment, the driving signal is voltage.

In step B3, the sensed signals can be voltage, current, electric quantity, capacity, or a variation value thereof before and after touching. In one embodiment, the sensed signals are represented by a variation value curve of the voltage. The variation value curve includes a plurality of voltage variation value before and after touching the touch panel 100. The variation value curve of the voltage detected from the plurality of first electrodes 104 is defined as a first curve, and the variation value curve of the voltage detected from the plurality of second electrodes 106 is defined as a second curve.

In step B4, the position coordinates of the touch points can be calculated according to the sensed signals obtained before and after touching the touch panel 100. In one embodiment, a method for calculating the position coordinates of the touch points acted on the touch panel 100 includes the following steps:

B41, calculating the position coordinates of the touch points in the high impedance direction H according to the first curve or the second curve; and

B42, calculating the position coordinates of the touch points in the low impedance direction D according to the first curve and the second curve.

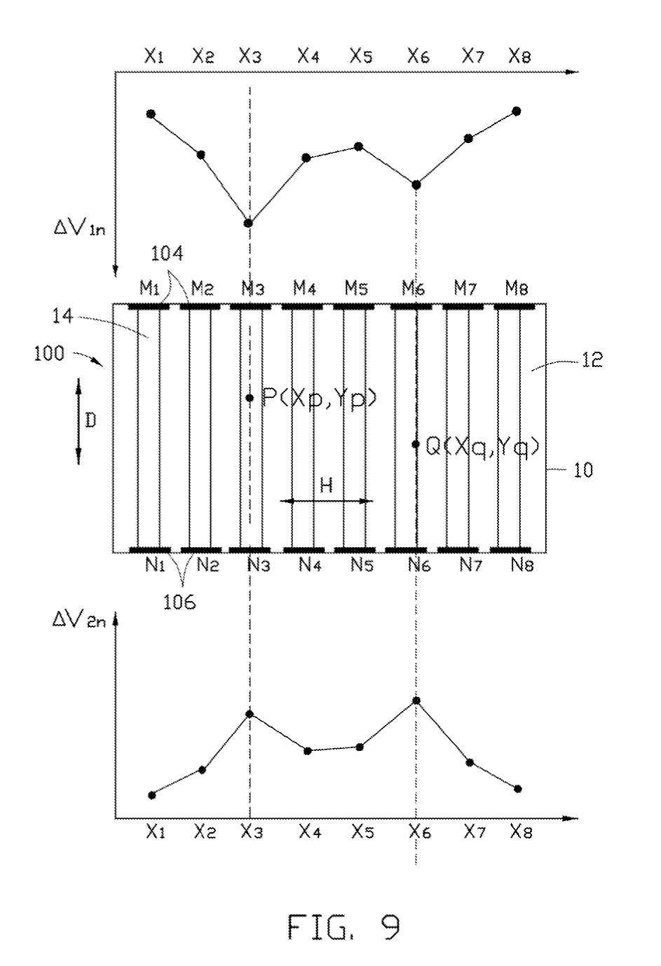

Referring to FIG. 9, P and Q represent two touch points acted on the touch panel 100 at the same time. The position coordinates of touch point P is represented by (xₚ, yₚ), and the position coordinates of the touch point Q is represented by (x_{q}, y_{q}). yₚ represents a distance perpendicular from the touch point P to the first side 112, and y_{q} represents a distance perpendicular from the touch point Q to the first side 112. The plurality of first electrodes 104 are labeled as M₁, M₂, M₃, M₄, M₅, M₆, M₇, and M₈. The plurality of second electrodes 106 are labeled as N₁, N₂, N₃, N₄, N₅, N₆, N₇, and N₈. The position coordinates of the plurality of first electrodes 104 and the plurality of second electrodes 106 in the high impedance direction H are orderly labeled as X₁, X₂, X₃, X₄, X₅, X₆, X₇, and X₈. ΔV₁ᵢ represents the variation value of the voltage detected from the first electrode Mᵢ before and after touching the touch panel 100. ΔV₂ᵢ represents the variation value of the voltage detected from the second electrode Nᵢ before and after touching the touch panel 100, wherein i represents a number order of the first or second electrode, and i=1, 2, . . . 8.

(1) Confirming the Position Coordinates of the Touch Points P and Q in the High Impedance Direction H

The position coordinates of the touch points P and Q in the high impedance direction H can be obtained from the first curve and the second curve. In one embodiment, one or more peak values in the first curve are found to calculate the position coordinates of the touch points P and Q in the high impedance direction H. Referring to FIG. 9, the variation value ΔV₁₃ detected from the M₃ and the variation value ΔV₁₆ detected from the M₆ are two peak values in the first curve. M₃ corresponds to the coordinate X₃ and M₅ corresponds to the coordinate X₅. Therefore, the position coordinates xₚ and x_{q} of the touch points P and Q can be directly judged from the first curve: xₚ=X₃, and x_{q}=X₅. In addition, the variation values detected from the electrodes adjacent to the electrodes in which the peak values are detected can be used to calculate the position coordinates of the touch points for a better precision. For example, M₂ and M₄ are adjacent to M₃, the position coordinate xₚ of the touch point P can be calculated by a formula:

$${x}_{p} = \frac{{X}_{2} Δ {V}_{12} + {X}_{4} {ΔV}_{14}}{Δ {V}_{12} + Δ {V}_{14}} .$$

Correspondingly, the position coordinate x_{q} can be calculated by a formula:

$${x}_{q} = \frac{{X}_{5} Δ {V}_{15} + {X}_{7} Δ {V}_{17}}{Δ {V}_{15} + Δ {V}_{17}} .$$

(2) Confirming the Position Coordinates of the Touch Points P and Q in the Low Impedance Direction D

The one or more peak values in the first curve and in the second curve are found to calculate the position coordinates of the touch points P and Q in the low impedance direction D. The transparent conductive film 10 has an anisotropic impedance property. The closer the touch points to the first electrodes 104 or the second electrodes 106 in the low impedance direction D, the greater the variation values detected from the corresponding first electrodes 104 or the corresponding second electrodes 106. Referring to FIG. 9, taking touch point P for example, a distance from the touch point P to the first electrode M₃ is smaller than the distance to the second electrode N₃, so the peak variation value ΔV₁₃ is greater than the peak variation value ΔV₂₃. The variation value is inversely proportional to the distance from the touch point to the corresponding first electrode 104 or second electrode 106. The position coordinate yₚ can be calculated by a formula:

$${y}_{p} = \frac{Δ {V}_{23}}{Δ {V}_{13} + Δ {V}_{23}} \times K ,$$

wherein K represents a distance perpendicular from the first side 112 to the second side 114. In addition, the variation values detected from the electrodes adjacent to the electrodes from which the peak values were detected can be used to calculate the position coordinates of the touch points in the low impedance direction D for a better precision. For example, the position coordinate yₚ can be represented by:

$${y}_{p} = \frac{Δ {V}_{22} + Δ {V}_{23} + Δ {V}_{24}}{Δ {V}_{13} + Δ {V}_{23} + Δ {V}_{12} + Δ {V}_{22} + Δ {V}_{14} + Δ {V}_{24}} \times K .$$

Other formulas can also be used to calculate the position coordinates of the touch points P and Q. The above method can detect two more touch points.

The transparent conductive film 10 has a good anisotropic impedance, a resistance diversity of the transparent conductive film 10 from one touch point to the different electrodes varies significantly. Consequently, a diversity of the signal variation values are detected from the different electrodes varies significantly. Therefore, one or more touch points can be detected according to a size or sizes of the variation values detected from the electrodes of the touch panel. In addition, a detecting precision of the touch points can be improved by the variation values which varied significantly.

Depending on the embodiment, certain steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

Finally, it is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

What is claimed is:

1. A transparent conductive film comprising:
at least one continuous transparent conductive layer; and
a plurality of transparent conductive stripes spaced from each other and extending substantially along a low impedance direction;
wherein the plurality of transparent conductive stripes are disposed on and electrically contact a surface of the at least one continuous transparent conductive layer, and a resistivity of the transparent conductive film in the low impedance direction is less than the resistivity in any other direction.

2. The transparent conductive film of claim 1, wherein the at least one continuous transparent conductive layer has substantially the same resistivities in any direction substantially parallel with the surface thereof, and a resistivity ratio of the plurality of transparent conductive stripes substantially along the extending direction and the at least one continuous transparent conductive layer is in a range from about 1:100 to about 1:1000.

3. The transparent conductive film of claim 1, wherein the plurality of transparent conductive stripes along the low impedance direction is longer than or substantially the same as the at least one continuous transparent conductive layer substantially along the low impedance direction.

4. The transparent conductive film of claim 1, wherein the plurality of transparent conductive stripes are continuous along the low impedance direction, each transparent conductive stripe extends from one side of the at least one continuous transparent conductive layer to an opposite side thereof, and the two sides are substantially perpendicular to the low impedance direction.

5. The transparent conductive film of claim 1, wherein the plurality of transparent conductive stripes are discontinuous along the low impedance direction.

6. The transparent conductive film of claim 1, wherein a material of the at least one continuous transparent conductive layer and the plurality of transparent conductive stripes is a transparent conductive material selected from the group consisting of metal oxide, metal nitride, metal fluoride, conductive polymer, graphene, and carbon nanotube transparent conductive film comprising a plurality of carbon nanotubes.

7. The transparent conductive film of claim 6, wherein the metal oxide comprises at least one of stannic oxide, zinc oxide, cadmium oxide, indium oxide, indium tin oxide, indium zinc oxide, gallium zinc oxide, and aluminum zinc oxide; the metal nitride comprises titanium nitride; the conductive polymer comprises at least one of poly(3,4-ethylenedioxythiophen) and a composition of PEDOT and polystyrene sulfonate.

8. The transparent conductive film of claim 1, wherein a material of the at least one continuous transparent conductive layer and the plurality of transparent conductive stripes are different.

9. The transparent conductive film of claim 8, wherein the material of the at least one continuous transparent conductive layer is a transparent conductive material selected from the group consisting of transparent conductive polymer, carbon nanotube transparent conductive film, and graphene sheet; the material of the plurality of transparent conductive stripes is the transparent conductive material selected from the group consisting of metal oxide, metal nitride, and metal fluoride.

10. The transparent conductive film of claim 9, wherein the at least one continuous transparent conductive layer is a composite film of the carbon nanotubes and PEDOT-PSS, the material of the plurality of transparent conductive stripes are indium tin oxide.

11. The transparent conductive film of claim 9, wherein the at least one continuous transparent conductive layer is a carbon nanotube drawn film comprising a plurality of carbon nanotubes extending substantially along a same direction, the material of the plurality of transparent conductive stripes are indium tin oxide, and the extending direction of a majority of carbon nanotubes in the carbon nanotube drawn film is substantially perpendicular to the extending direction of the plurality of transparent conductive stripes.

12. The transparent conductive film of claim 1, wherein the plurality of transparent conductive stripes is selected from the group consisting of a straight stripe, a square wave stripe, a waved stripe, a zigzag stripe, a stepped shaped stripe, a cambered stripe, and combinations thereof.

13. The transparent conductive film of claim 1, wherein a width of one of the plurality of transparent conductive stripes is varied.

14. The transparent conductive film of claim 1, wherein the at least one continuous transparent conductive layer is a free-standing structure.

15. A transparent conductive film comprising:
a continuous transparent conductive layer; and
a plurality of transparent conductive stripes spaced from each other and electrically connected via the continuous transparent conductive layer,
wherein a resistivity of the plurality of transparent conductive stripes is less than the resistivity of the continuous transparent conductive layer.

16. A touch panel comprising:
a substrate,
at least one transparent conductive film disposed on a surface of the substrate, and
a plurality of electrodes spaced from each other and electrically connected with the at least one transparent conductive film;
wherein the at least one transparent conductive film comprises at least one continuous transparent conductive layer and a plurality of transparent conductive stripes spaced from each other and extending substantially along a low impedance direction, the plurality of transparent conductive stripes are disposed on and electrically contact a surface of the at least one continuous transparent conductive layer, and a resistivity of the transparent conductive film in the low impedance direction is less than the resistivity in any other direction.

17. The touch panel of claim 16, wherein the plurality of electrodes are electrically connected with at least one end of the plurality of transparent conductive stripes.

18. The touch panel of claim 16, wherein a distance between adjacent transparent conductive stripes is less than or equal to 50 micrometers.
